(19) United States
(12) Patent Application Publication
(10) Pub. No.: US 2014/0357070 A1
(43) Pub. Date: Dec. 4, 2014

(54) METHOD OF IMPROVING THE YIELD OF A SEMICONDUCTOR DEVICE

(71) Applicant: Shanghai Huali Microelectronics Corporation, Shanghai (CN)

(72) Inventors: HongJun YU, Shanghai (CN); Fei Zhou, Shanghai (CN); Ying Xu, Shanghai (CN)

(73) Assignee: Shanghai Huali Microelectronics Corporation, Shanghai (CN)

(21) Appl. No.: 14/085,321

(22) Filed: Nov. 20, 2013

(30) Foreign Application Priority Data
Jun. 4, 2013 (CN) CN 201310222267.0

(51) Int. Cl. H01L 21/28

(52) U.S. Cl. CPC H01L 21/28035
USPC 438/585

(57) ABSTRACT

A method of improving the yield of semiconductor devices includes implanting ions into a NMOS gate. A layer of PEOX film is deposited upon the gate. A layer of LTO film is deposited upon the PEOX film. The method solves the problems of ions implanted on the NMOS gate diffusing to the structure of the PMOS gate due to the high temperature annealing process which impairs the electrical characteristic of the PMOS; the aggregation and precipitation of the ions to the surface of the gate due to the porosity of PEOX film, which impairs the active area of NMOS in the subsequent etching process; that the LTO film is easily influenced by the lower layer film and is affected by the speed of surface atom diffusion of the lower layer thereby avoiding differences in thickness of LTO film deposited on NMOS and PMOS.

### CROSS-REFERENCE TO RELATED APPLICATION

The present application claims priority under the Paris Convention to Chinese application number CN 201310222267.0, filed on Jun. 4, 2013, the disclosure of which is herewith incorporated by reference in its entirety.

### BACKGROUND OF THE INVENTION

1. Field of the Invention

The present invention relates to a semiconductor device manufacturing process and, in particular, it relates to a method for improving the device yield.

2. Description of the Prior Art

Semiconductor devices, such as memory, Dynamic Random Access Memory (hereinafter “DRAM”) and Static Random Access Memory (hereinafter “SRAM”) indicates the level of integrated circuit technology of a country and a company due to its own characteristic, high integration level, high integration density and high manufacturing difficulty. The integration level of DRAM increases at a speed over 200 percent every three years internationally. So is SRAM. Presently, the 16 Mb SRAM which use 0.35 um technology has been developed internationally. The 64 Mb CMOS (Complementary Metal Oxide Semiconductor) SRAM is applied to the testing chip. SRAM, particularly, the high speed buffer SRAM is the basic components of high-performance computers. The high speed SRAM is also needed for high speed test systems and high speed data collection systems.

It is reported that memory accounts for about 30 percent of total sales in the global semiconductor product market. SRAM accounts for about 22 percent of the total amount of all types of memory, which grows 21 percent every year.

The main process of producing CMOS SRAM can also be applied to the manufacturing of other types of the Integrated Circuits (hereinafter “IC”), such as the logic circuits and application specific integrated circuit. Hence, the yield of SRAM is extremely important as SRAM is an extreme important part of ICs.

In SRAM PMOS and NMOS are of the gate structure. As shown in FIG. 1, the top view structure diagram of the sharing polysilicon gate of NOMS and PMOS, P Well Region 101 and N Well Region 102 is formed on the semiconductor substrate. N Active Area 104 is set in the P Well Region 101. P active area 105 is set in N Well Region 102. A Sharing Polysilicon Gate layer 103 is deposited into the upper surface of the P Well Region 101 and N Well Region 102. FIG. 2 is a profile structure diagram of the sharing polysilicon gate of NOMS and PMOS. P Well Region 101 and N Well Region 102 is formed in the semiconductor substrate, which has a Shallow Trench Isolation Structure 106 to isolate NMOS and PMOS. A Sharing Polysilicon Gate Layer 103 is deposited into the upper surface of P Well Region 101 and N Well Region 102. Due to the electrical difference of NMOS and PMOS, ions are usually implanted into the gate structure of NMOS to suppress the depletion of the polysilicon and to reduce the electrical thickness of the gate oxide layer. Therefore, after the ion implantation of NMOS gate, three methods are adopted to produce the gate hard mask.

FIG. 3 is a structure diagram that illustrates the horizontal diffusion of NMOS gate ion in high temperature annealing process of Method 1 in the prior art. FIG. 3 shows that in Method 1, after ions are implanted into the NMOS gate, the high temperature annealing process is applied to the NMOS gate. Next, a layer of low temperature oxide (“LTO”, hereinafter) is deposited upon the polysilicon gate. Damage to the active area is not detected after subsequent etching process. However, due to the high temperature in high temperature annealing process, the ions implanted to the NMOS gate 107 are diffused by the gate structure of PMOS horizontally. Consequently, it impairs the electrical characteristic of PMOS and further decrease the yield of SRAM.

FIG. 4 is a profile structure diagram of damaged area of the NMOS active area after the etching process in Method 2 in the prior art. FIG. 5 is the top view structure diagram of damaged area of the NMOS active area after the etching process in Method 2 in the prior art. As shown in FIGS. 4 and 5, in Method 2 a layer of plasma enhanced oxide (hereinafter “PEOX”) is deposited upon the polysilicon gate after the ions are implanted into the NMOS gate. PEOX is also called radio frequency low-temperature plasma enhanced silicon dioxide thin film, which is created by the reaction of silane and nitrous oxide at the temperature of 400° C. PEOX is very loose. It makes polysilicon and implanting ions diffuse. Therefore, after the N type Gate Structure 108 is formed by the subsequent etching process, it is inevitable that the NMOS active area will be damaged. As shown in FIG. 4, the defect and the notch in the NMOS active area are formed. As shown in FIG. 5, Defects 110 decrease the yield of SRAM.

FIG. 6 is a structure diagram that shows the film thickness of NMOS gate and PMOS gate after the hard mask layer deposition in Method 3 in the prior art. As shown in FIG. 6, in Method 3, after ions are implanted into the NMOS gate, a LTO of 400 A is deposited upon the polysilicon gate straightly without being annealed. LTO is created by the reaction of ozone and TEOS at the low temperature of 400° C. LTO is porous or loose. The tensile strength of LTO is large and LTO film is easily influenced by the lower layer film. The forming speed of LTO film is affected by the speed of surface atom diffusion of the lower layer, leading to differences in thickness of LTO film deposited on NMOS and PMOS. Ions are implanted into the NMOS gate aggregate on the surface of NMOS gate layer to a certain extent. The thickness of the LTO Film 109 which is deposited on the NMOS and PMOS is different. It impairs the subsequent etching process and decreases the yield of SRAM.

Chinese Patent (Publication Number: CN101567313A) discloses a method of gate manufacture, including: a substrate, where the gate oxide layer, the polysilicon layer, the hard mask layer and the patterning photo resist layer are formed in turn. The patterning photo resist layer is used as mask. The hard mask layer is etching to form the patterning hard mask layer. Meanwhile, the patterning photo resist layer is partially removed. The removed patterning photo resist layer and the patterning hard mask layer are used as masks. The polysilicon layer and the gate oxide layer are etched. Meanwhile, the patterning photo resist layer is removed entirely. The patterning hard mask layer is partially removed. The gate is formed after removing remaining patterning hard mask layer.

Chinese patent (Publication Number: CN102148149A) discloses a method of forming a semiconductor device gate, including the following steps: (a) A substrate, on which the gate oxide layer, the polysilicon layer, the dielectric layer, the bottom antireflective layer is formed in turn. And finally, the patterning photo resist is formed; (b) The patterning photo resist is used as mask. The bottom antireflective layer and the dielectric layer are etched to form the patterning bottom antireflective layer and the patterning dielectric layer. At last, the photo resist is removed; (c) The patterning bottom antireflective layer and the patterning dielectric layer are used as a mask. The gate is formed on the patterning polysilicon layer by patterning the polysilicon layer and etching the gate oxide layer. By adopting this method, the outlines of a gate are improved, and the stability of the device and the yield of device are increased.

The two aforementioned devices can avoid photo resist residue phenomenon or improve the outlines of the gate, increasing the yield of semiconductor. However, they do not solve the problem of ions implanted to NMOS gate diffusing to the structure of the PMOS gate due to the high temperature during the annealing process which impairs electrical characteristic of the PMOS. These prior devices have also failed to solve the problems of the ions implanted to the NMOS gate diffusing to the surface of the gate due to the loosing of PEOX film, which impairs the active area of NMOS in the subsequent etching process. Further, they did not solve the problem that LTO film exhibits high tensile strength and LTO film is easily influenced by the lower layer film. The forming speed of LTO film is affected by the speed of surface atom diffusion of the lower layer, leading to differences in thickness of LTO film deposited on NMOS and PMOS. The subsequent etching process is impaired which leads to the problem of decreasing semiconductor yield.

### SUMMARY OF THE INVENTION

Due to the defects of the traditional art, the present invention discloses a method of improving the yield of semiconductor devices by using a process of producing a gate in a substrate including a first well region and a second well region, comprising the steps of:

depositing a sharing gate layer upon the upper surface of the substrate, and ions are implanted into said sharing gate layer which is located on the top of the first well region;

a PEOX film is deposited, which covers the upper surface of said sharing gate layer;

an LTO film is deposited, which covers the upper surface of said PEOX film;

a first type gate structure and a second type gate structure are formed by photoetching and etching process and removing the remaining PEOX film and LTO film;

wherein the PEOX film is the plasma enhanced oxide film.

According to the above method, wherein said first well region is a P well region, said second well region is an N well region, and said first type gate structure is formed above said P Well Region, said second type gate structure is formed above said N Well Region.

According to the above method, wherein, said first type gate structure is the N type gate structure, and said second type gate structure is the P type gate structure.

According to the above method, the ion source of the ion implantation process is phosphorus.

According to the above method, a hard mask layer is made up of said PEOX film and said LTO film.

According to the above method, said PEOX film is deposited by plasma enhanced chemical vapor deposition.

According to the above method, said PEOX film is deposited at the temperature from 390° C. to 410° C.

According to the above method, the thickness of said PEOX film is from 80 Å to 120 Å.

According to the above method, the LTO film is deposited by the Chemical vapor deposition at low temperature.

According to the above method, said LTO film is deposited by the plasma enhanced chemical vapor deposition.

According to the above method, said LTO film is deposited at the temperature from 390° C. to 410° C.

According to the above method, the thickness of said LTO film is from 280 Å to 320 Å.

According to the above method, said etching process is dry etching or wet etching.

The beneficial effects and the advantages of the above invention are as follows:

after ions are implanted into the NMOS gate, a layer of PEOX film is deposited, and then a layer of LTO film is deposited on the PEOX film. The invention solves the problem that the ions implanted to the NMOS gate diffuse to the structure of PMOS gate impairing electrical characteristic of PMOS. It also solves the problem that the ions that are implanted to NMOS gate aggregate and precipitate in the surface gate due to the loose or porous property of PEOX film, which impairs the active area of NMOS in the subsequent etching process. It further solves the problem that LTO film has a high tensile strength. LTO film is easily influenced by the lower layer film. The forming speed of LTO film is affected by the speed of surface atom diffusion of the lower layer, leading to differences in thickness of LTO film deposited on NMOS and PMOS. The subsequent etching process is impaired which leads to the problem of decreasing semiconductor yield.

### BRIEF DESCRIPTION OF THE DRAWINGS

FIG. 1 is a top view of a structure diagram of a sharing polysilicon gate of NMOS and PMOS;

FIG. 2 is a profile structure diagram of the sharing polysilicon gate of NMOS and PMOS;

FIG. 3 is a structure diagram showing the horizontal diffusion of the NMOS gate ions high temperature annealing process of Method 1 in the prior art;

FIG. 4 is a profile structure diagram of a damaged area of the NMOS active area after the etching process in Method 2 in the prior art;

FIG. 5 is a top view structure diagram of a damaged area of the NMOS active area after the etching process in Method 2 in the prior art;

FIG. 6 is a structure diagram that shows the film thickness of NMOS gate and PMOS gate after using a hard mask layer deposition of using Method 3 in the prior art;

FIG. 7 is a block or flow processing diagram illustrating the process for improving the semiconductor device yield according to the invention;

FIG. 8 is a structure diagram of the NMOS gate according to an embodiment of the invention, which has been implanted with the ion implanting process;

FIG. 9 is a structure diagram of the NMOS gate according to an embodiment of the invention, where PEOX film is deposited;

FIG. 10 is a structure diagram of the NMOS gate according to an embodiment of the invention, where LTO film is deposited;

FIG. 11 is a structure diagram of NMOS according to an embodiment of the invention, which has been etched; and

FIG. 12 is a structure diagram of PMOS according to an embodiment of the invention, which has been etched.

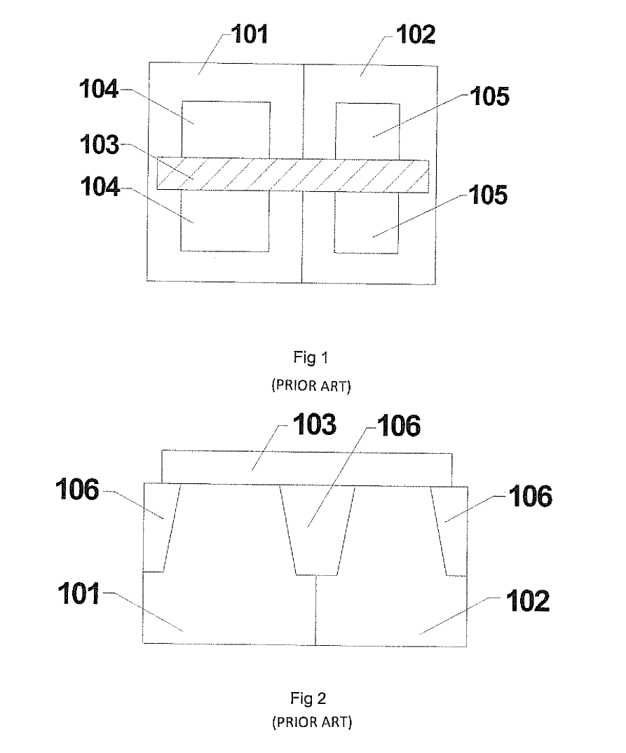

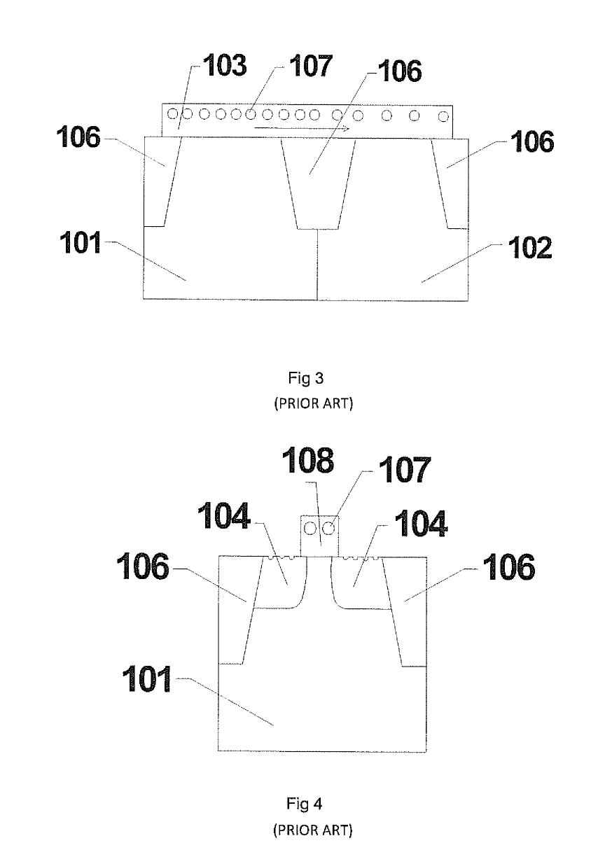

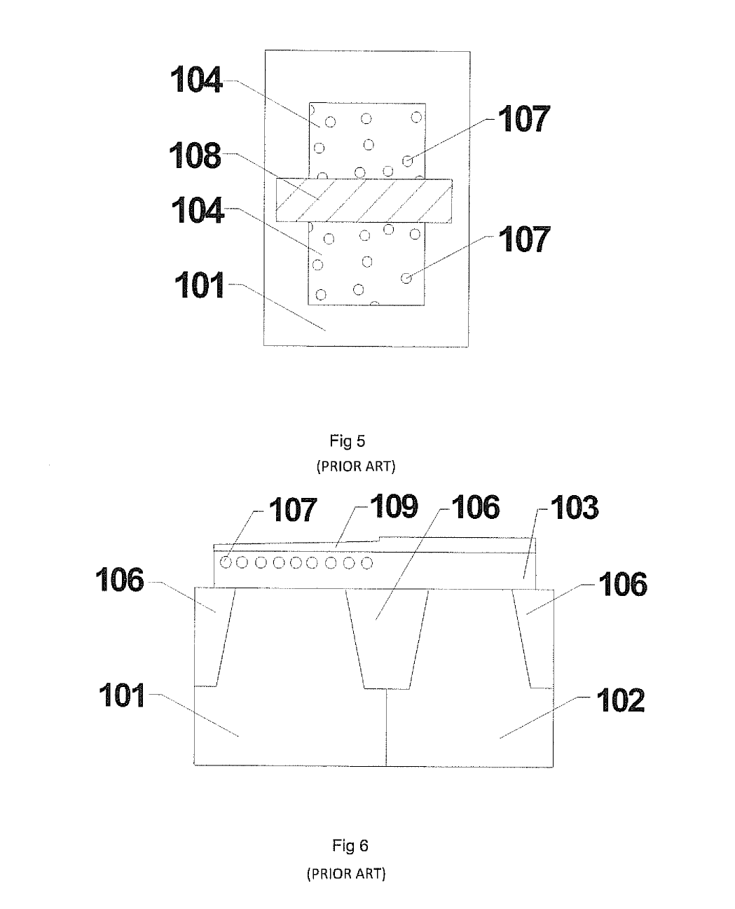

### DETAILED DESCRIPTION OF THE PREFERRED EMBODIMENT

The present invention will be further illustrated by way of example with reference to the following figures and embodiments, without limitation of the present invention.

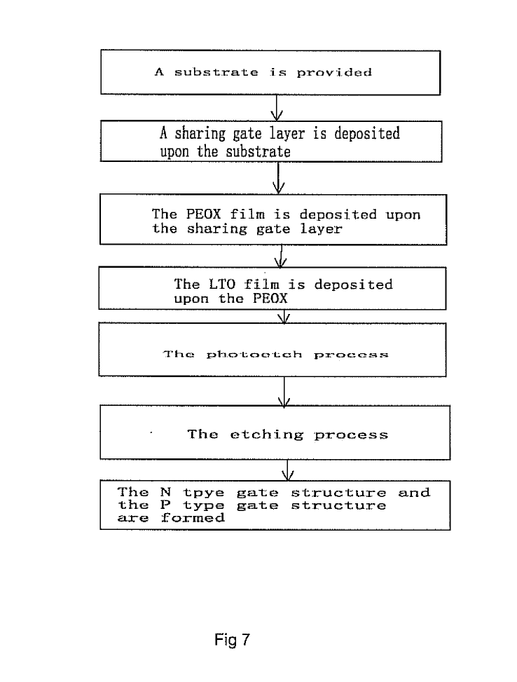

FIG. 7 is the process diagram for improving the semiconductor device yield according to the present invention. As shown in FIG. 7, a substrate is provided which includes a P Well Region and am N well region. A sharing gate layer is deposited upon the upper surface of P well region and N well region. A PEOX film is deposited upon the sharing gate layer by plasma enhanced chemical vapor deposition, and then a LTO film is deposited upon the PEOX film by the low temperature chemical vapor deposition. The PEOX film and the LTO film jointly form a hard mask. After the process of photoetching and the etching process, a N type gate structure is formed in P well region, and a P type gate structure is formed in N well region.

The method is preferably applied to the gate process of 65 nm or 55 nm technology nodes, and it is also preferably applied to the semiconductor manufacturing of logical circuit, which is more suitable to application of the semiconductor manufacturing of memory.

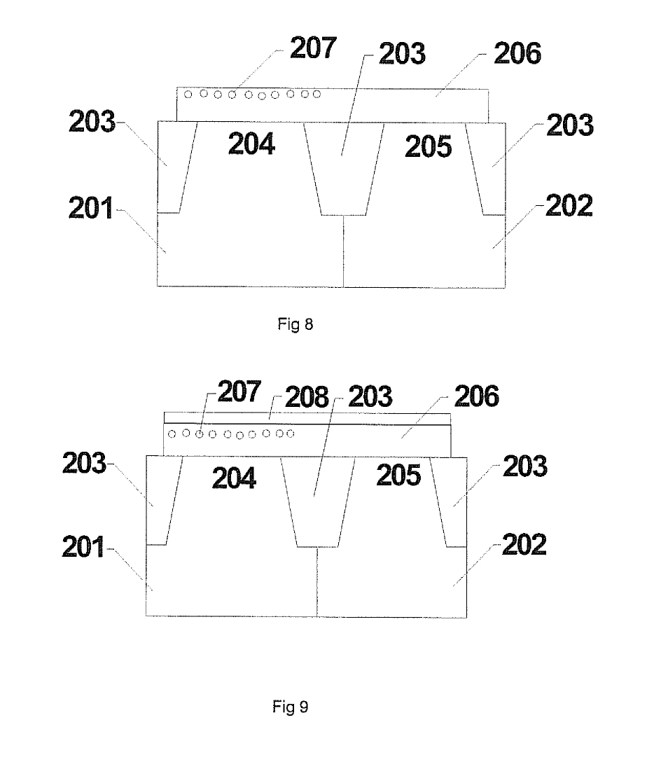

FIG. 8 is the structure diagram of the NMOS gate in the embodiment of the invention, which has been implanted with the ion implanting process. As shown in FIG. 8, a substrate includes P Well Region 201 and N Well Region 202. N type Active Area 204 of NMOS is set in the P Well Region 201, and the P type Active Area 205 of PMOS is set in the N Well Region 202, P Well Region 201 and N Well Region 202 are separated from each other by a Shallow Trench Isolation Structure 203, which also separates the N type structure and the P type structure which are formed in the N type Active Area 204 and the P type Active Area 205. Shallow Trench Isolation Structure 203 is formed in the area which is adjacent to the N well region and P well region, the depth thereof is larger than that of the N type active area and the P type active area which are formed in the subsequent process, and is shorter than that of P well region and N well region. A Sharing Gate Layer 206 is deposited in the P well region and N well region, which is a polysilicon layer. The area of Sharing Gate Layer 206 is implanted with ion implanting process in P well region, and Ions 207 is phosphorus ions.

FIG. 9 is the structure diagram of the NMOS gate in the embodiment of the invention, where the PEOX film is deposited. After the ion implanting process to the area of the P well region in NMOS corresponds to the Sharing Gate Layer 206, a PEOX Film 208 is deposited upon the Sharing Gate Layer 206 by the plasma enhanced chemical vapor deposition with silane and nitrous oxide at the temperature from 390° C. to 410° C., such as 390° C., 395° C., 400° C., 405° C., or 410° C., and so on. The thickness of the PEOX film ranges from 80 Å to 120 Å, such as 80 Å, 90 Å, 100 Å, 110 Å, or 120 Å, and so on. The PEOX film covers the upper surface of Sharing Gate Layer 206. The tensile strength of PEOX film is large and LTO film is easily influenced by the lower layer film. The forming speed of LTO film is affected by the speed of surface atom diffusion of the lower layer, leading to differences in thickness of LTO film deposited on NMOS and PMOS. This impairs the subsequent etching process, bringing about decreasing the semiconductor device yield.

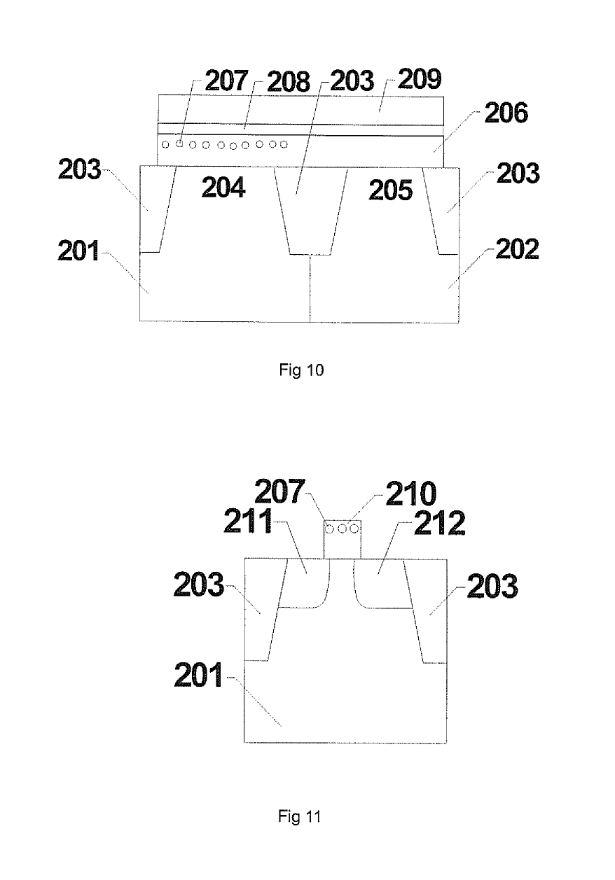

FIG. 10 is the structure diagram of the NMOS gate in the embodiment of the invention, where the LTO film is deposited. As shown in FIG. 10, when the PEOX film has been deposited, the LTO Film 209 is deposited upon the PEOX Film 208 by the plasma enhanced chemical vapor deposition with TEOS and ozone at the temperature of 390° C. to 410° C., such as 390° C., 395° C., 400° C., 405° C., or 410° C., and so on. The thickness of LTO ranges from 280 Å to 320 Å, such as 280 Å, 290 Å, 300 Å, 310 Å, or 320 Å and so on. LTO Film 209 covers the upper surface of the PEOX Film 208, which solved the problem that the ions which are implanted into the gate of the NMOS separates out at the surface of the gate and the active region of the NMOS may be damaged after being etched, which are caused by the loosing of the PEOX film.

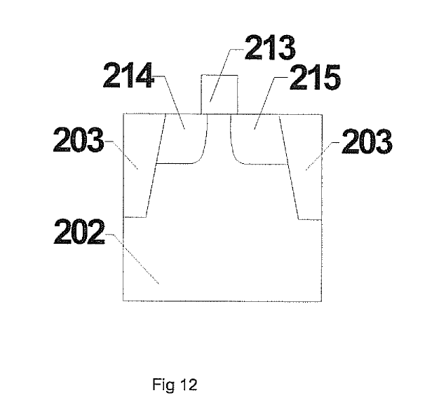

In the PEOX film and the LTO film jointly form a hard mask layer, the process of forming the hard mask layer does not contain the annealing process. As a result, it solved the problem of the electric characteristic which is affected by the ions implanted into the gate of the NMOS diffusing into the gate of the PMOS. FIG. 11 is the structure diagram of NMOS in the embodiment of the invention, which has been etched. FIG. 12 is the structure diagram of PMOS in the embodiment of the invention, which has been etched. As shown in FIGS. 11 and 12, after the deposition process of the LTO film, the photoresist is coated on the LTO film, for example, using spin coating method, and then doing the following steps of prebaking, exposure, postbaking, preharden and developing, and then the LTO film, PEOX film and sharing gate layer are etched by wet etch or dry etch, so that a N type Gate Structure 210 and the P type Gate Structure 213 is formed on the semiconductor device. The ions are implanted into the well region and the active region of the semiconductor device. N type Active Structures 211 and 212 are formed in two sides of the N type gate structure to which the P well region corresponds, and the P type Active Structures 214 and 215 are formed in two sides of the P type gate structure to which N well region corresponds. Consequently, the semiconductor device gate process is accomplished, in addition, overcoming three above problem in prior art, and the semiconductor device yield will be improved.

Although a typical embodiment of a particular structure of the specific implementation way has been given with the above description and the figures, it is appreciated that other changes based on the spirit of this invention may also be made. Though the preferred embodiments are proposed above, these are not intended to be the limitation of this invention.

It is obvious for the skilled in the art to make varieties of changes and modifications after reading the above descriptions. Hence, the Claims attached should be regarded as all the changes and modifications which cover the real intention and the range of this invention. Any and all equivalent contents and ranges in the range of the Claims should be regarded belonging to the intention and the range of this invention.

1. A method of improving the yield of semiconductor device, which is applied to the process of producing a gate in a substrate, said substrate involves the first well region and the second well region, wherein involves following steps:
depositing a sharing gate layer is deposited upon the upper surface of the substrate, and implanting ions into said sharing gate layer which is located on the top of the first well region;
depositing a PEOX film which covers the upper surface of said sharing gate layer is deposited;
depositing a LTO film which covers the upper surface of said PEOX film;
forming a first type gate structure and a second type gate structure are formed by photoetching and etching process and removing the remaining PEOX film and LTO film;
wherein the PEOX film is the plasma enhanced oxide film.

2. The method according to claim 1, wherein said first well region is the P well region, said second well region is the N well region, and said first type gate structure is formed above said P well region, said second type gate structure is formed above said N well region.

3. The method according to claim 1, wherein said first type gate structure is the N type gate structure, and said second type gate structure is the P type gate structure.

4. The method according to claim 2, wherein said first type gate structure is the N type gate structure, and said second type gate structure is the P type gate structure.

5. The method according to claim 1, wherein the ion source of said ions which are implanted into said sharing gate layer is phosphorus.

6. The method according to claim 1, wherein a hard mask layer is made up of said PEOX film and said LTO film.

7. The method according to claim 1, wherein said PEOX film is deposited by the plasma enhanced chemical vapor deposition.

8. The method according to claim 7, wherein said PEOX film is deposited at the temperature ranging from 390° C. to 410° C.

9. The method according to claim 8, wherein the thickness of said PEOX film ranges from 80 Å to 120 Å.

10. The method according to claim 1, wherein the LTO film is deposited by low temperature chemical vapor deposition.

11. The method according to claim 10, wherein said LTO film is deposited by plasma enhanced chemical vapor deposition.

12. The method according to claim 10, wherein said LTO film is deposited at temperature ranging from 390° C. to 410° C.

13. The method according to claim 12, wherein the thickness of said LTO film ranges from 280 Å to 320 Å.

14. The method according to claim 1, wherein said etching process is dry etching or wet etching.
